(19) United States
(12) Patent Application Publication
(10) Pub. No.: US 2016/0027840 A1
(43) Pub. Date: Jan. 28, 2016

(54) SOLID-STATE IMAGING DEVICE

(71) Applicant: Kabushiki Kaisha Toshiba, Minato-ku (JP)

(72) Inventor: Tadashi IIJIMA, Kawasaki-shi (JP)

(73) Assignee: Kabushiki Kaisha Toshiba, Minato-ku (JP)

(21) Appl. No.: 14/878,046

(22) Filed: Oct. 8, 2015

Related U.S. Application Data
(62) Division of application No. 14/199,214, filed on Mar. 6, 2014.

(30) Foreign Application Priority Data
Aug. 13, 2013 (JP) 2013-168284

(51) Int. Cl. H01L 27/146

(52) U.S. Cl. CPC H01L 27/14685; H01L 27/14625; H01L 27/14623

(57) ABSTRACT

According to one embodiment, a solid-state imaging device includes a first light-receiving portion and a first light guide layer. The first light-receiving portion is formed in the surface of a semiconductor substrate. The first light guide layer is formed to correspond to a portion above the first light-receiving portion, and has an inverse tapered shape in which the width becomes larger from an upper surface a lower surface. The inverse tapered shape ranges from the upper surface the lower surface.

### CROSS-REFERENCE TO RELATED APPLICATIONS

This application is a division of and claims the benefit of priority under 35 U.S.C. §120 from U.S. Ser. No. 14/199,217 filed Mar. 6, 2014, and claims the benefit of priority under 35 U.S.C. §119 from Japanese Patent Application No. 2013-168284 filed Aug. 13, 2013, the entire contents of each of which are incorporated herein by reference.

### FIELD

Embodiments described herein relate generally to a solid-state imaging device.

### BACKGROUND

In a digital camera, a video camera, or the like, a solid-state imaging device is used to image an object. The solid-state imaging device includes a pixel array in which a plurality of pixels are arrayed in a matrix. Each pixel includes a microlens, a color filter, a light guide layer, and a light-receiving portion (photodiode). In each pixel, light having entered the microlens passes through the color filter, and is focused on the light-receiving portion through the light guide layer.

In general, the light guide layer is formed by forming a trench in an interlayer dielectric layer, and filling in the trench. That is, the shape of the light guide layer is the shape of the trench formed in the interlayer dielectric layer. The trench formed in the interlayer dielectric layer is formed to have a tapered shape in which the width becomes smaller from the upper side to the lower side due to a manufacturing method. The light guide layer, therefore, has a tapered shape in which the width becomes smaller from the upper side (microlens side) to the lower side (light-receiving portion side).

However, if the light guide layer has a tapered shape, it is difficult to suppress the reflection components to the upper side of the light having entered the side surface of the light guide layer, thereby decreasing the reflection efficiency to the lower side. That is, the focusing property of the light-receiving portion positioned on the lower side of the light guide layer degrades.

### BRIEF DESCRIPTION OF THE DRAWINGS

FIG. 1 is a block diagram showing the schematic arrangement of a digital camera including a solid-state imaging device according to the first embodiment;

FIG. 2 is a block diagram showing the schematic arrangement of the solid-state imaging device according to the first embodiment;

FIG. 3 is a sectional view showing the arrangement of imaging pixels in the solid-state imaging device according to the first embodiment;

FIGS. 4, 5, 6, 7, and 8 are sectional views showing a process of manufacturing the imaging pixels in the solid-state imaging device according to the first embodiment;

FIG. 9 is a view showing incidence and reflection of light on a light guide layer according to a comparative example;

FIG. 10 is a view showing incidence and reflection of light on a light guide layer according to the first embodiment;

FIG. 11 is a sectional view showing the arrangement of phase difference detection pixels in a solid-state imaging device according to the second embodiment; and

FIG. 12 is a sectional view showing a modification of the arrangement of the phase difference detection pixels in the solid-state imaging device according to the second embodiment.

### DETAILED DESCRIPTION

In general, according to one embodiment, a solid-state imaging device includes a first light-receiving portion and a first light guide layer. The first light-receiving portion is formed in the surface of a semiconductor substrate. The first light guide layer is formed to correspond to a portion above the first light-receiving portion, and has an inverse tapered shape in which the width becomes larger from an upper surface a lower surface. The inverse tapered shape ranges from the upper surface the lower surface.

This embodiment will be described below with reference to the accompanying drawings. The same reference numerals denote the same parts throughout the drawings. A repetitive description will be made, as needed.

### First Embodiment

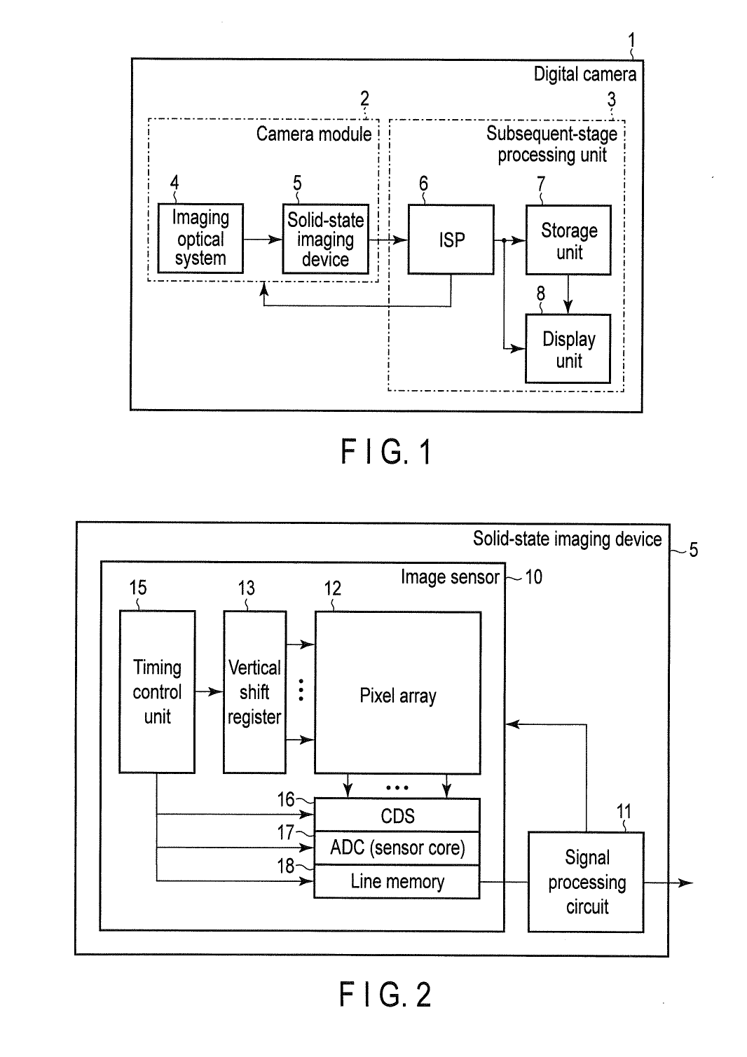

A solid-state imaging device according to the first embodiment will be explained below with reference to FIGS. 1, 2, 3, 4, 5, 6, 7, 8, 9, and 10.

In the first embodiment, a light guide layer 35 in each pixel (imaging pixel 30) has an inverse tapered shape in which the width becomes larger from the upper side to the lower side. This can improve the reflection efficiency to the lower side of light having entered the side surface of the light guide layer 35, thereby improving the focusing property of a light-receiving portion 32. The first embodiment will be described in detail below.

[Arrangement]

The arrangement of the solid-state imaging device according to the first embodiment will be described with reference to FIGS. 1, 2, and 3.

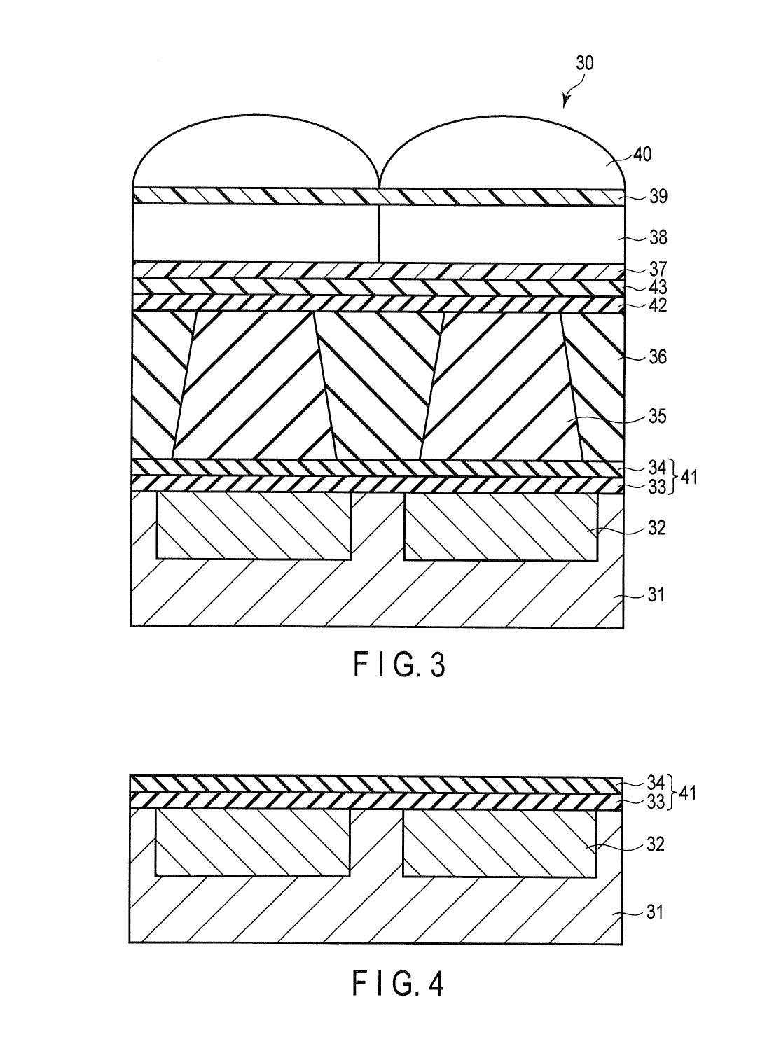

FIG. 1 is a block diagram showing the schematic arrangement of a digital camera including the solid-state imaging device according to the first embodiment. FIG. 2 is a block diagram showing the schematic arrangement of the solid-state imaging device according to the first embodiment.

As shown in FIG. 1, a digital camera 1 includes a camera module 2 and a subsequent-stage processing unit 3. The camera module 2 includes an imaging optical system 4 and a solid-state imaging device 5. The subsequent-stage processing unit 3 includes an ISP (Image Signal Processor) 6, a storage unit 7, and a display unit 8. The camera module 2 is applied to, for example, an electric device such as a mobile terminal with a camera, in addition to the digital camera 1.

The imaging optical system 4 captures light from an object, and forms an object image. The solid-state imaging device 5 captures the object image. The ISP 6 performs signal processing for an image signal obtained by the capturing operation in the solid-state imaging device 5. The storage unit 7 stores an image having undergone the signal processing in the ISP 6. In response to a user operation or the like, the storage unit 7 outputs an image signal to the display unit 8. The display unit 8 displays an image corresponding to the image signal input from the ISP 6 or storage unit 7. The display unit 8 is, for example, a liquid crystal display. Furthermore, the data having undergone the signal processing in the ISP 6 is fed back to the camera module 2.

As shown in FIG. 2, the solid-state imaging device 5 includes a signal processing circuit 11 and an image sensor 10 serving as an imaging element. The image sensor 10 is, for example, a CMOS image sensor. Instead of the CMOS image sensor, the image sensor 10 may be a CCD.

The image sensor 10 includes a pixel array 12, a vertical shift register 13, a timing control unit 15, a CDS (Correlation Double Sampling) unit 16, an ADC (analog-to-digital converter (sensor core)) 17, and a line memory 18. The pixel array 12 is arranged in the imaging region of the image sensor 10. The pixel array 12 includes a plurality of pixels which are arranged in an array in the horizontal (row) and vertical (column) directions. Each pixel includes a photodiode serving as a photoelectric conversion element. The pixel array 12 generates a signal charge corresponding to the amount of light entering each pixel. The generated signal charges are converted into digital data through the CDS and ADC, and output to the signal processing circuit 11. The signal processing circuit 11 performs, for example, lens shading correction, flaw correction, and noise reduction processing. The data having undergone the signal processing is output to, for example, the outside of the chip, and is simultaneously fed back to the image sensor 10.

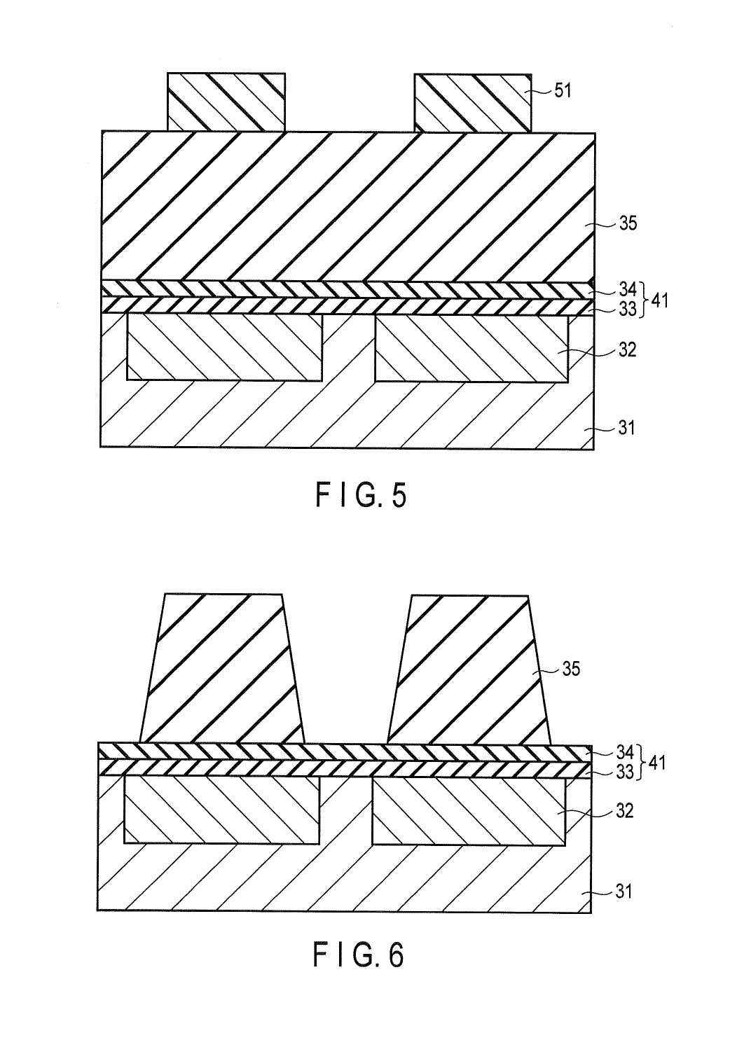

FIG. 3 is a sectional view showing the arrangement of the imaging pixels in the solid-state imaging device according to the first embodiment. FIG. 3 shows two adjacent imaging pixels 30.

As shown in FIG. 3, each imaging pixel 30 includes the light-receiving portion 32, the light guide layer 35, a color filter 38, and a microlens 40.

The light-receiving portions 32 are formed in the surface of a semiconductor substrate 31 made of, for example, Si. Each light-receiving portion 32 is formed by, for example, an n-type layer formed in the surface of a p-type well in the semiconductor substrate 31. The light-receiving portion 32 is, for example, a photodiode, and converts incident light into an electric charge and accumulates it.

An antireflection film 41 having a stacked structure including a first layer 33 and a second layer 34 which have been sequentially formed from the lower side is formed on the light-receiving portions 32 and the semiconductor substrate 31. That is, the antireflection film 41 is formed between the light guide layers 35 (to be described later) and the light-receiving portions 32 and semiconductor substrate 31. The refractive index of the first layer 33 is lower than that of the semiconductor substrate 31 and that of the second layer 34. The refractive index of the second layer 34 is higher than that of the first layer 33 and lower than that of the semiconductor substrate 31. This allows the antireflection film 41 to prevent reflection of light entering from the upper side, thereby improving the light incident efficiency to the light-receiving portion 32. The first layer 33 is made of, for example, SiO_{X} (for example, SiO₂), and the second layer 34 is made of, for example, SiN. Alternatively, the first layer 33 is made of, for example, SiO_{X}, and the second layer 34 is made of, for example, HfO_{Y} (for example, HfO₂).

Each light guide layer 35 is formed on the antireflection film 41 so as to correspond to a portion above a corresponding one of the light-receiving portions 32. In other words, each light guide layer 35 and its corresponding light-receiving portion 32 overlap each other in a plane. The planar shape of the light guide layer 35 is, for example, a circle. Therefore, the light guide layer 35 has, for example, a cylindrical shape. The light guide layer 35 has an inverse tapered shape in which the width (diameter) becomes larger from the upper surface (the side of the microlens 40) to the lower surface (the side of the light-receiving portion 32). In other words, the light guide layer 35 includes an opening having a width larger on the side of the light-receiving portion 32 than on the side of the microlens 40. Furthermore, the light guide layer 35 has an inverse tapered shape from the upper surface to the lower surface. The light guide layer 35 has a refractive index higher than that of an interlayer dielectric layer 36 (to be described later), and is made of, for example, SiN.

The interlayer dielectric layer 36 is formed on the antireflection film 41 to be embedded between the two adjacent light guide layers 35. In other words, the interlayer dielectric layer 36 is formed around the light guide layers 35. The height of the upper surface of the interlayer dielectric layer 36 is almost equal to that of the upper surface of each light guide layer 35. That is, each light guide layer 35 is formed within the interlayer dielectric layer 36 to extend (penetrate) from its upper surface to its lower surface. The interlayer dielectric layer 36 has a refractive index lower than that of the light guide layer 35, and is made of, for example, SiO_{X}. Note that an “almost equal height” indicates a substantially equal height.

A first insulating layer 42 made of, for example, SiN is formed on the light guide layers 35 and interlayer dielectric layer 36. A second insulating layer 43 made of, for example, SiO_{X} is formed on the first insulating layer 42. The first insulating layer 42 and second insulating layer 43 are formed as protection films for an element (not shown) which is formed on the semiconductor substrate 31. This can improve the element characteristics.

A planarization layer 37 is formed on the second insulating layer 43. This can improve the flatness of the upper surface, thereby facilitating formation of the color filters 38 (to be described later). Although the planarization layer 37 is formed by an organic film which is formed by, for example, a coating method, the present invention is not limited to this.

Each color filter 38 is formed on the planarization layer 37 so as to correspond to a portion above a corresponding one of the light guide layers 35. In other words, each color filter 38 and its corresponding light guide layer 35 overlap each other in a plane. Light having passed through the color filter 38 enters the light-receiving portion 32, thereby obtaining a color image.

A planarization layer 39 is formed on the color filters 38. This can improve the flatness of the upper surface, thereby facilitating formation of the microlenses (to be described later). Although the planarization layer 39 is formed by an organic film which is formed by, for example, a coating method, the present invention is not limited to this.

Each microlens 40 is formed on the planarization layer 39 so as to correspond to a portion above a corresponding one of the color filters 38. In other words, each microlens 40 and its corresponding color filter 38 overlap each other in a plane. The microlens 40 focuses incident light on the corresponding light-receiving portion 32.

Note that an interconnection (not shown) is formed between the two adjacent imaging pixels 30. For example, the interconnection is formed between the semiconductor substrate 31 and the first insulating layer 42 and second insulating layer 43 which are formed on the light guide layers 35 and interlayer dielectric layer 36.

The interconnection is connected to an element (not shown) formed on the semiconductor substrate 31. The element converts collected electrons into a signal, and performs a shutter operation (for example, an electron emission operation).

[Manufacturing Method]

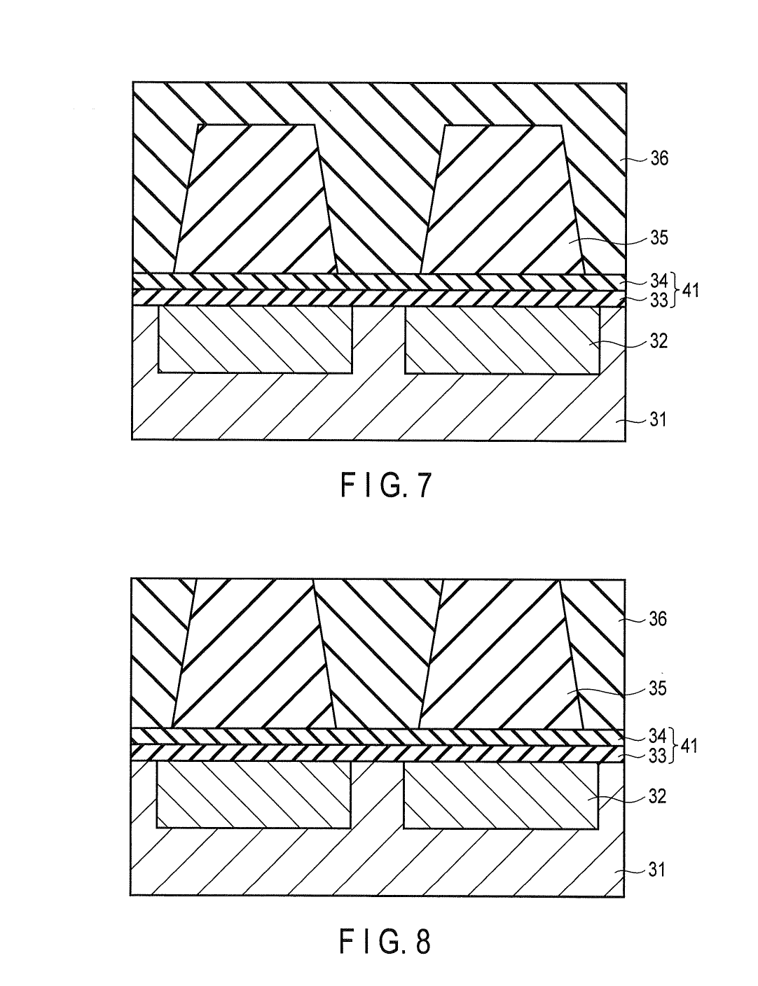

A method of manufacturing the solid-state imaging device according to the first embodiment will be described with reference to FIGS. 4, 5, 6, 7, and 8.

FIGS. 4, 5, 6, 7, and 8 are sectional views showing a process of manufacturing the imaging pixels in the solid-state imaging device according to the first embodiment.

As shown in FIG. 4, light-receiving portions 32 are formed in the surface of a semiconductor substrate 31. After p-type wells are formed in the semiconductor substrate 31, n-type layers are formed in the surfaces of the p-type wells, thereby forming the light-receiving portions 32.

A first layer 33 and a second layer 34 are formed on the light-receiving portions 32 and semiconductor substrate 31 by, for example, CVD (Chemical Vapor Deposition). This forms an antireflection film 41 having a stacked structure including the first layer 33 and the second layer 34. The first layer 33 is made of, for example, SiO_{X}, and the second layer 34 is made of, for example, SiN. Alternatively, the first layer 33 is made of, for example, SiO_{X}, and the second layer 34 is made of, for example, HfO_{Y}.

As shown in FIG. 5, a light guide layer 35 is formed on the entire surface of the antireflection film 41 by, for example, CVD. The light guide layer 35 has a refractive index higher than that of the interlayer dielectric layer 36, and is made of, for example, SiN. After that, a resist 51 is formed on the light guide layer 35, and patterned by lithography. As a result, the resist pattern 51 remains to correspond to portions above the light-receiving portions 32. The planar shape of the resist pattern 51 is, for example, a circle.

As shown in FIG. 6, the light guide layer 35 is patterned by RIE (Reactive Ion Etching) using the resist pattern 51 as a mask. Consequently, the light guide layers 35 are formed on the antireflection film 41 so as to correspond to portions above the light-receiving portions 32, respectively. In other words, each light guide layer 35 and its corresponding light-receiving portion 32 overlap each other in a plane. The planar shape of each light guide layer 35 is, for example, a circle. Therefore, each light guide layer 35 has, for example, a cylindrical shape.

In this case, the light guide layer 35 is patterned by predetermined RIE, and thus formed to have an inverse tapered shape. More specifically, the light guide layer 35 is formed to have an inverse tapered shape in which the width (diameter) becomes larger from the upper surface (the side of the microlens 40) to the lower surface (the side of the light-receiving portion 32). In other words, the light guide layer 35 includes an opening having a width larger on the side of the light-receiving portion 32 than on the side of the microlens 40. Furthermore, the light guide layer 35 is formed to have an inverse tapered shape ranging from its upper surface to its lower surface.

After that, the resist pattern 51 is removed by, for example, asking.

As shown in FIG. 7, an interlayer dielectric layer 36 is formed on the entire surface by, for example, CVD. With this processing, the interlayer dielectric layer 36 is embedded between the two adjacent light guide layers 35 on the antireflection film 41. In other words, the interlayer dielectric layer 36 is formed around the light guide layers 35. The interlayer dielectric layer 36 is also formed on the light guide layers 35. The interlayer dielectric layer 36 has a refractive index lower than that of the light guide layers 35, and is made of, for example, SiO_{X}.

As shown in FIG. 8, the upper surface of the interlayer dielectric layer 36 is planarized by, for example, CMP (Chemical Mechanical Polishing). Consequently, the height of the upper surface of the interlayer dielectric layer 36 is almost equal to that of the upper surface of each light guide layer 35. That is, each light guide layer 35 is formed within the interlayer dielectric layer 36 to extend (penetrate) from its upper surface to its lower surface.

As shown in FIG. 3, a first insulating layer 42 is formed on the light guide layers 35 and interlayer dielectric layer 36 by, for example, CVD. A second insulating layer 43 is formed on the first insulating layer 42 by, for example, CVD. The first insulating layer 42 is made of, for example, SiN, and the second insulating layer 43 is made of, for example, SiO_{X}. The first insulating layer 42 and the second insulating layer 43 are formed as protection films for an element (not shown) which is formed on the semiconductor substrate 31.

A planarization layer 37 is formed on the second insulating layer 43 by, for example, a coating method. Although the planarization layer 37 is formed by, for example, an organic film, the present invention is not limited to this. Subsequently, a color filter 38 is formed on the planarization layer 37 so as to correspond to a portion above each light guide layer 35. A planarization layer 39 is formed on the color filters 38 by, for example, a coating method. Although the planarization layer 39 is formed by, for example, an organic film, the present invention is not limited to this. After that, a microlens 40 is formed on the planarization layer 39 so as to correspond to a portion above each color filter 38.

As described above, the imaging pixels in the solid-state imaging device according to the first embodiment are formed.

Note that before forming the planarization layer 37, an interconnection may be formed by forming an insulating layer (not shown) on the light guide layers 35 and the interlayer dielectric layer 36, forming a trench in the insulating layer on the interlayer dielectric layer 36, and further forming a conductive layer in the trench. Note also that the present invention is not limited to such damascene method, and an interconnection may be formed by forming a patterned conductive layer on the interlayer dielectric layer 36, and forming an insulating layer on the entire surface.

[Effects]

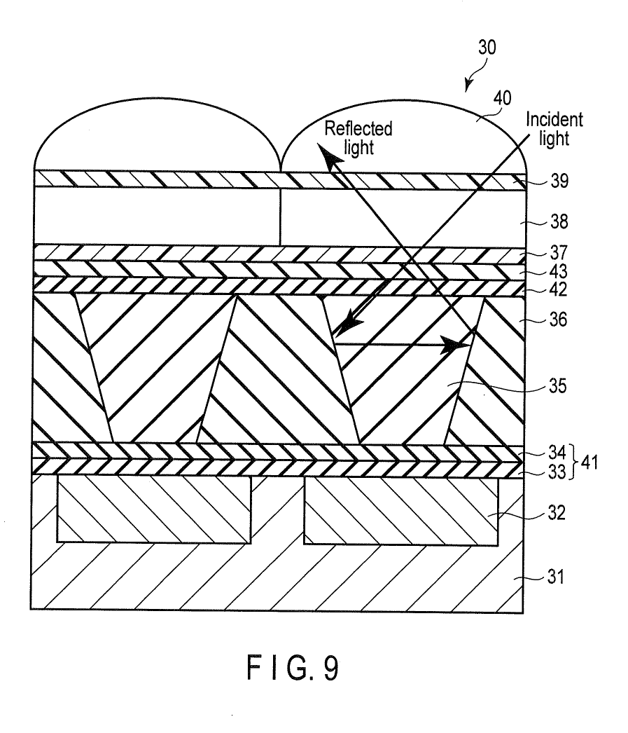

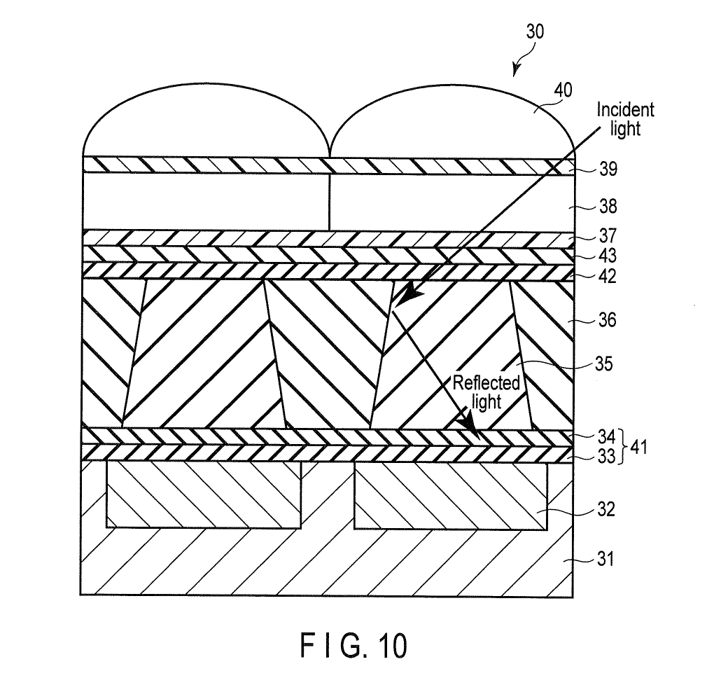

FIG. 9 is a view showing incidence and reflection of light on a light guide layer according to a comparative example. FIG. 10 is a view showing incidence and reflection of light on the light guide layer according to the first embodiment.

In the comparative example, as shown in FIG. 9, a light guide layer 35 has a tapered shape in which the width becomes smaller from the upper surface (the side of a microlens 40) to the lower surface (the side of a light-receiving portion 32). In this case, the side surface (reflection surface) of the light guide layer 35 faces in the upper direction with respect to the vertical direction. As shown in FIG. 9, therefore, especially when light having a large incident angle (a large angle with respect to the vertical direction) enters the light guide layer 35, it is repeatedly reflected on the side surface of the light guide layer 35, and is finally reflected in the upper direction. As a result, the focusing property of the light-receiving portion 32 positioned on the lower side degrades.

To the contrary, in the above-described first embodiment, as shown in FIG. 10, the light guide layer 35 has an inverse tapered shape in which the width becomes larger from the upper surface (the side of the microlens 40) to the lower surface (the side of the light-receiving portion 32). In this case, the side surface (reflection surface) of the light guide layer 35 faces in the lower direction with respect to the vertical direction. Therefore, as shown in FIG. 10, even if light having a large incident angle enters the light guide layer 35, it is reflected on the side surface of the light guide layer 35 in the lower direction. As a result, the reflection efficiency of the incident light to the lower direction can be increased, thereby improving the focusing property of the light-receiving portion 32.

Furthermore, in the first embodiment, the light guide layer 35 and interlayer dielectric layer 36 are formed so that their upper surfaces and lower surfaces have the same heights. Then, an inverse tapered shape is formed so as to range from the upper surface to lower surface of the light guide layer 35. This makes it possible to improve the light reflection efficiency to the lower direction, as compared with a case in which an inverse tapered shape is formed in only part of the light guide layer 35.

### Second Embodiment

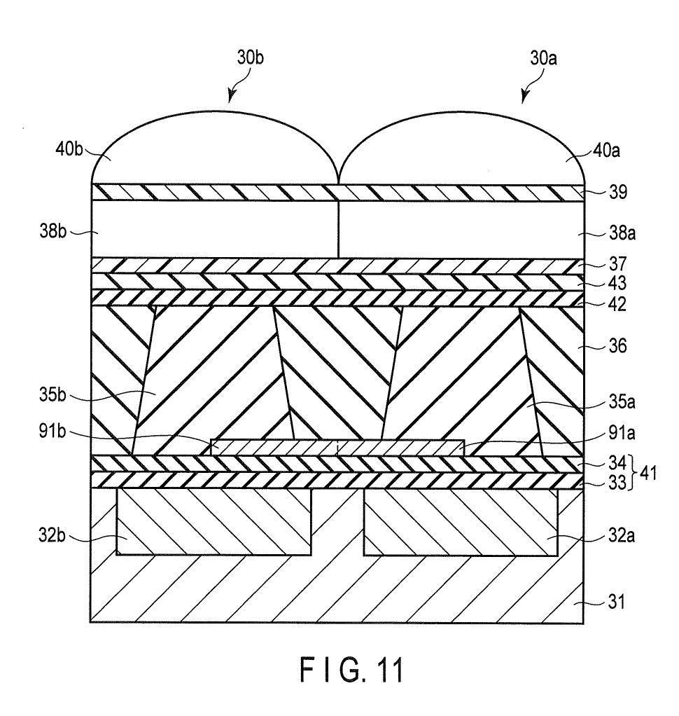

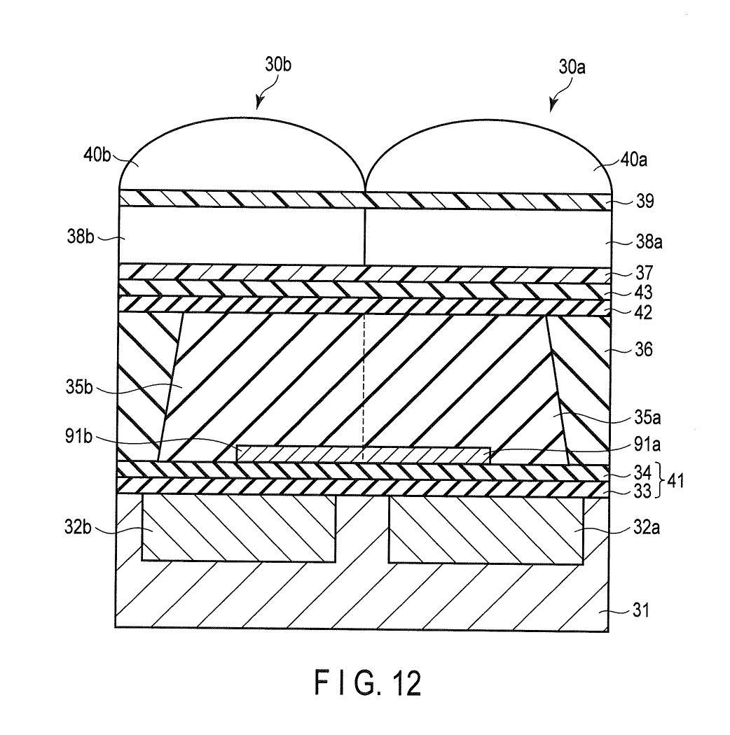

A solid-state imaging device according to the second embodiment will be described below with reference to FIGS. 11 and 12.

In the second embodiment, a case in which the structure of the light guide layer 35 according to the first embodiment is applied to phase difference detection pixels (a first phase difference detection pixel 30a and a second phase difference detection pixel 30b) for performing autofocus will be explained. That is, each phase difference detection pixel includes a light-shielding film 91a or 91b. This can improve the focusing property of the light-receiving portion 32a or 32b in the phase difference detection pixel. The second embodiment will be described in detail below.

Note that in the second embodiment, a description of the same points as in the first embodiment will be omitted, and different points will be mainly described.

<Arrangement>

The arrangement of the solid-state imaging device according to the second embodiment will be explained with reference to FIGS. 11 and 12.

FIG. 11 is a sectional view showing the arrangement of the phase difference detection pixels in the solid-state imaging device according to the second embodiment. FIG. 11 shows two adjacent phase difference detection pixels (the first phase difference detection pixel 30a and second phase difference detection pixel 30b).

As shown in FIG. 11, the second embodiment is different from the first embodiment in that the adjacent first and second phase difference detection pixels 30a and 30b have the light-shielding films 91a and 91b, respectively.

The first phase difference detection pixel 30a includes the light-receiving portion 32a, a light guide layer 35a, a color filter 38a, a microlens 40a, and the light-shielding film 91a. The second phase difference detection pixel 30b includes the light-receiving portion 32b, a light guide layer 35b, a color filter 38b, a microlens 40b, and the light-shielding film 91b.

In the first phase difference detection pixel 30a, the light-shielding film 91a is formed on an antireflection film 41 so as to correspond to a portion above part of the light-receiving portion 32a. More specifically, the light-shielding film 91a is formed to cover one half (left half on the side of the second phase difference detection pixel 30b) of the light-receiving portion 32a. In other words, the light-shielding film 91a includes an opening which exposes the other half (right half on the opposite side of the second phase difference detection pixel 30b) of the light-receiving portion 32a. That is, the light-shielding film 91a is positioned on one side of the bottom layer of the light guide layer 35a. With this arrangement, among light beams from respective directions which are focused on the microlens 40a, light beams which enter from the left side are blocked by the light-shielding film 91a without entering the light-receiving portion 32a.

On the other hand, in the second phase difference detection pixel 30b, the light-shielding film 91b is formed on the antireflection film 41 so as to correspond to a portion above part of the light-receiving portion 32b. More specifically, the light-shielding film 91b is formed to cover the other half (right half on the side of the first phase difference detection pixel 30a) of the light-receiving portion 32b. In other words, the light-shielding film 91b includes an opening which exposes one half (left half on the opposite side of the first phase difference detection pixel 30a) of the light-receiving portion 32b. That is, the light-shielding film 91b is positioned on the other side of the bottom layer of the light guide layer 35b. With this arrangement, among light beams from respective directions which are focused by the microlens 40b, light beams which enter from the right side are blocked by the light-shielding film 91b without entering the light-receiving portion 32b.

As described above, the first phase difference detection pixel 30a is configured to prevent light entering from the left side of the microlens 40a from entering the light-receiving portion 32a, and the second phase difference detection pixel 30b is configured to prevent light entering from the right side of the microlens 40b from entering the light-receiving portion 32b. That is, the first phase difference detection pixel 30a and the second phase difference detection pixel 30b (the light-shielding films 91a and 91b) are formed to have mirror symmetry. A shift occurs between an image formed by the imaging signal of the first phase difference detection pixel 30a and an image formed by the imaging signal of the second phase difference detection pixel 30b in the lateral direction according to the focus state of a photographing lens which forms an object image. By detecting the amount and direction of the shift between the image formed by the imaging signal of the first phase difference detection pixel 30a and that formed by the imaging signal of the second phase difference detection pixel 30b, it is possible to obtain the focus adjustment amount of the photographing lens.

Note that the first phase difference detection pixel 30a and the second phase difference detection pixel 30b can be used not only in autofocusing but also in forming an image in combination with imaging pixels 30.

The light-shielding films 91a and 91b are formed to be connected to each other between the adjacent first and second phase difference detection pixels 30a and 30b. In other words, the light-shielding films 91a and 91b are regarded as one film. The light-shielding films 91a and 91b are made of a metal such as Al (aluminum) or W (tungsten) which can block light.

FIG. 12 is a sectional view showing a modification of the arrangement of the phase difference detection pixels in the solid-state imaging device according to the second embodiment. FIG. 12 shows two adjacent phase difference detection pixels (first phase difference detection pixel 30a and second phase difference detection pixel 30b).

According to the modification, as shown in FIG. 12, between the adjacent first and second phase difference detection pixels 30a and 30b, light-shielding films 91a and 91b are formed to be connected to each other and light guide layers 35a and 35b are formed to be connected to each other. In other words, no interlayer dielectric layer 36 is formed between the light guide layers 35a and 35b.

This is because it is possible to prevent light from entering from an adjacent pixel by forming the light-shielding films 91a and 91b to be connected to each other, without isolating the light guide layers 35a and 35b from each other. That is, the light-shielding films 91a and 91b can prevent light having entered the first phase difference detection pixel 30a (microlens 40a) from entering the light-receiving portion 32b of the second phase difference detection pixel 30b, and also prevent light having entered the second phase difference detection pixel 30b (microlens 40b) from entering the light-receiving portion 32a of the first phase difference detection pixel 30a.

[Manufacturing Method]

A method of manufacturing the solid-state imaging device according to the second embodiment will be described next.

The same process as that shown in FIG. 4 according to the first embodiment is performed first. That is, an antireflection film 41 is formed on light-receiving portions 32 and a semiconductor substrate 31.

Light-shielding films 91a and 91b are formed on the antireflection film 41.

If the light-shielding films 91a and 91b are made of Al, they are formed by performing RIE for an Al layer. That is, the light-shielding films 91a and 91b are formed by forming an Al layer on the entire surface of the antireflection film 41, and patterning the Al layer by RIE.

On the other hand, the light-shielding films 91a and 91b are made of W, the light-shielding films 91a and 91b are formed by performing a damascene method for a W layer. That is, the light-shielding films 91a and 91b are formed by forming an insulating layer (for example, SiO₂) (not shown) on the entire surface of the antireflection film 41, forming a trench in the insulating layer, and embedding a W layer in the trench. Note that the insulating layer may be removed thereafter.

If the light-shielding films 91a and 91b are made of W, they may be formed by performing RIE for a W layer, similarly to a case in which they are made of Al. That is, the light-shielding films 91a and 91b may be formed by forming a W layer on the entire surface of the antireflection film 41, and patterning the W layer by RIE.

The light-shielding film 91a which covers one side of the light-receiving portion 32a and the light-shielding film 91b which covers the other side of the light-receiving portion 32b are thus formed.

Subsequently, the same process as that described with reference to FIGS. 5, 6, 7, and 8 in the first embodiment is performed. That is, a light guide layer 35a is formed on the antireflection film 41 and the light-shielding film 91a, and a light guide layer 35b is formed on the antireflection film 41 and the light-shielding film 91b. After that, an interlayer dielectric layer 36, a planarization layer 37, color filters 38a and 38b, a planarization layer 39, and microlenses 40a and 40b are sequentially formed.

As described above, the phase difference detection pixels in the solid-state imaging device according to the second embodiment are formed.

[Effects]

According to the above-described second embodiment, the light-shielding films 91a and 91b are formed to cover parts of the light-receiving portions 32a and 32b, respectively. With this processing, the first phase difference detection pixel 30a and the second phase difference detection pixel 30b for performing autofocus are formed. By applying the structure of the light guide layer 35 in the first embodiment to the first phase difference detection pixel 30a and the second phase difference detection pixel 30b, it is possible to improve the focusing properties of the light-receiving portions 32a and 32b in the first phase difference detection pixel 30a and the second phase difference detection pixel 30b, respectively.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

1. A method of manufacturing a solid-state imaging device, comprising:
forming a first light-receiving portion in a surface of a semiconductor substrate; and
forming a first light guide layer so as to correspond to a portion above the first light-receiving portion, the first light guide layer having an inverse tapered shape in which a width becomes larger from an upper surface to a lower surface, the inverse tapered shape ranging from the upper surface to the lower surface,
wherein the forming of the first light guide layer comprises
forming the first light guide layer on an entire surface of the semiconductor substrate, and
patterning the first light guide layer.

2. The method of claim 1, wherein
the patterning of the first light guide layer comprises
forming a patterned resist on the first light guide layer, and
etching the first light guide layer by RIE using the resist as a mask.

3. The method of claim 1, further comprising:
forming an interlayer dielectric layer around the first light guide layer after forming the first light guide layer.

4. The method of claim 3, wherein
a height of an upper surface of the first light guide layer is equal to that of an upper surface of the interlayer dielectric layer.

5. The method of claim 3, wherein
the first light guide layer includes SiN, and the interlayer dielectric layer includes SiO₂.

6. The method of claim 1, further comprising:
forming an antireflection film on the first light-receiving portion after forming the first light-receiving portion.

7. The method of claim 6, wherein
the antireflection film comprises a first layer including SiO₂ and a second layer including SiN, which have been sequentially formed from a side of the first light-receiving portion.

8. The method of claim 1, further comprising:
forming a first light-shielding film above the first light-receiving portion so as to cover part of the first light-receiving portion after forming the first light-receiving portion.

9. The method of claim 8, wherein
in the forming of the first light-receiving portion, a second light-receiving portion is formed in the surface of the semiconductor substrate to be adjacent to the first light-receiving portion,
in the forming of the first light guide layer, a second light guide layer having an inverse tapered shape in which a width becomes larger from an upper surface to a lower surface is formed to correspond to a portion above the second light-receiving portion, the inverse tapered shape ranging from the upper surface to the lower surface, and
in the forming of the first light-shielding film, a second light-shielding film is formed above the second light-receiving portion to cover part of the second light-receiving portion and to be connected to the first light-shielding film.

10. The method of claim 9, wherein
the first light guide layer and the second light guide layer are formed to be connected to each other.
